(19) United States
(12) Patent Application Publication
(10) Pub. No.: US 2021/0057588 A1
(43) Pub. Date: Feb. 25, 2021

(54) MEMRISTOR WITH TWO-DIMENSIONAL (2D) MATERIAL HETEROJUNCTION AND PREPARATION METHOD THEREOF

(71) Applicant: Huazhong University of Science & Technology, Wuhan (CN)

(72) Inventors: Wei XIONG, Wuhan (CN); Wenguang ZHANG, Wuhan (CN); Leimin DENG, Wuhan (CN); Jingwei LIU, Wuhan (CN); Hao WU, Wuhan (CN); Jun DUAN, Wuhan (CN)

(21) Appl. No.: 16/999,570

(22) Filed: Aug. 21, 2020

(30) Foreign Application Priority Data
Aug. 22, 2019 (CN) 201910779092.0

(51) Int. Cl. H01L 29/86; H01L 29/66; H01L 29/45; H01L 21/02

(52) U.S. Cl. CPC H01L 29/86; H01L 29/66969; H01L 29/24; H01L 21/02614; H01L 29/45

(57) ABSTRACT

A memristor with a two-dimensional (2D) material heterojunction and a preparation method thereof is provided. The memristor includes a substrate, a bottom electrode layer, a 2D material heterojunction layer and a top electrode layer from bottom to top. The 2D material heterojunction layer serves as an intermediate dielectric layer, and has a two-layer laminate structure composed of two different transitional metal dichalcogenides (TMDCs), with one layer in the laminate structure corresponding to one of the TMDCs. The present invention constructs a novel memristor totally based on 2D materials by improving the materials used for key functional layers in the device and the design for the overall structure of the device. Compared with the prior art, the present invention completely different from the conventional metal/insulator/metal (MIM) structure, and has advantages, such as lower operating voltage, excellent retention and switching stability.

### CROSS-REFERENCE TO RELATED APPLICATIONS

This application claims priority to Chinese Patent Application No. 201910779092.0, filed on Aug. 22, 2019, the disclosure of which is incorporated by reference herein in its entirety for all purposes.

### TECHNICAL FIELD

The present invention relates generally to the technical field of microelectronics, and in particular, relates to a memristor with a two-dimensional (2D) material heterojunction and a preparation method thereof.

### BACKGROUND

In 1971, professor Leon O. Chua, from the University of California, Berkeley, boldly predicted from the perspective of physical symmetry that, in addition to the three known fundamental passive components of circuit, including resistor, capacitor and inductor, there should also be a fourth fundamental element “memristor,” whose resistance depends on the history of the input current or voltage, that is, the memristor has memories. Thirty-seven years later, the engineers of HP Labs announced in Nature magazine that a fourth fundamental circuit component had been physically discovered for the first time, which immediately attracted great attention from the electronics industry globally.

Although the appearance of memristors has triggered an upsurge of research worldwide, and much important progress has been made, the research on memristors still faces many challenges. The overall performance level of an existing memristor is far from meeting the requirements of actual applications (such as high-density mass resistive random-access memory and artificial neuron circuit), and also can hardly meet requirements in industrial applications, such as small size (nanoscale), low energy consumption (low voltage and low current), high speed, high stability and good retention. In particular, the requirements of small size and low energy consumption are technical points that must be overcome to expand the application of memristors.

At present, researches are mainly focused on memristors based on metal/insulator/metal (MIM) sandwich structure globally. Traditional insulation materials and metal electrode materials such as metal oxides are the main objects of research at present, with a long research history and high technological maturity. The memristive dielectric layer mainly includes an insulation material, such as binary metal oxides and perovskite complex oxides. However, due to the limitations of the material itself in mechanics and optics, it is difficult to meet the requirements of flexibility and transparency in future applications. Moreover, it also faces many challenges in various aspects, such as device dimensions, stability and operating voltage.

In addition, the use of emerging functional nanomaterials (especially 2D nanomaterials) brings an opportunity to develop an ultra-thin, flexible and transparent memristor with high performance. However, at present, 2D materials are mainly used to improve the functions of some materials in a conventional MIM-type memristor. For example, the introduction of graphene, graphene oxide (GO), and single-layer molybdenum disulfide can significantly improve the performance of a memristor. Currently, no one has provided a technical solution to construct a novel memristor totally based on 2D materials.

### SUMMARY

In view of the above defects or improving requirements of the prior art, the present invention is intended to provide a memristor with a 2D material heterojunction and a preparation method thereof. The present invention constructs a novel memristor totally based on 2D materials by improving the materials used for key functional layers in the device, the design for the overall structure of the device, and the design for the overall process of the preparation method. Compared with the prior art, the present invention is completely different from the conventional MIM structure, and has many advantages, such as lower operating voltage, excellent retention and switching stability. In addition, the memristor exhibits a high degree of similarity to the information transmission by synapses when mimicking the information transmission by neurons, and has a promising prospect in the development of a brain-like computer system in the future.

To achieve the above purpose, the present invention provides a memristor with a two-dimensional (2D) material heterojunction, including a substrate, a bottom electrode layer, a 2D material heterojunction layer and a top electrode layer from bottom to top, where, the 2D material heterojunction layer serves as an intermediate dielectric layer with a thickness of 1 nm to 50 nm, and has a two-layer laminate structure composed of two different transitional metal dichalcogenides (TMDCs), with one layer in the laminate structure corresponding to one of the TMDCs.

Further preferably, the 2D material heterojunction layer is formed by directly sulfurating a metal laminate structure in high purity sulfur vapor; the metal laminate structure includes two layers of elemental metal structures; and the two layers include metal elements different from each other.

Further, the direct sulfuration is conducted at 500° C. to 1,000° C. for 1 min to 30 min; and preferably, the 2D material heterojunction layer has a thickness of 10 nm, and the direct sulfuration is conducted at 550° C. for less than 10 min.

Further, the two different TMDCs are specifically two different transition metal disulfides; and preferably, the TMDCs are any two of zinc sulfide, silver sulfide, titanium sulfide, cadmium sulfide, cuprous sulfide, germanium sulfide, tungsten sulfide and molybdenum sulfide.

Further, the substrate is a rigid substrate or a flexible and transparent substrate; and the substrate can withstand a high temperature of at least 500° C., and will not react with the sulfur vapor; and preferably, the rigid substrate is a SiO₂/Si substrate with an oxide layer formed from oxidation of the monocrystalline silicon surface, or a sapphire substrate.

Further, the top electrode layer is Au, Ti, Pt, Al, W, Ag, Cu, ITO, TiN or graphene, with a thickness of 80 nm to 200 nm; preferably, the top electrode layer is Al, with a thickness of 100 nm.

The material used for the bottom electrode layer is any one of metal, conductive oxide, conductive nitride and conductive carbon material, with a thickness of 1 nm to 500 nm; and preferably, the material used for the bottom electrode layer is a conductive oxide, preferably ITO with a thickness of 10 nm to 1,000 nm, and more preferably ITO with a thickness of 200 nm.

The present invention further provides a method for preparing the above memristor with a 2D material heterojunction, including the following steps: (1) preparing a clean substrate provided with a bottom electrode layer on the surface thereof; (2) depositing a metal laminate structure on the bottom electrode layer by a thin film deposition process with a shadow mask, where, the thin film deposition process is thermal evaporation, magnetron sputtering, electron beam evaporation, sol-gel, chemical vapor deposition or coating; (3) treating, using a direct vacuum sulfuration method, the substrate deposited with the metal laminate structure, so that the metal laminate structure is sulfurated to form a TMDCs heterojunction structure; and (4) spin-coating a photoresist on the heterojunction structure, and defining a top electrode pattern on the photoresist by lithography; then depositing electrode materials for forming a top electrode layer, and then stripping the photoresist to form the top electrode layer, thereby achieving the preparation of the memristor with a 2D material heterojunction.

Further, in step (2), the metal laminate structure is preferably deposited on the bottom electrode layer by magnetron sputtering or electron beam evaporation; in step (2), the metal laminate structure is a two-layer metal structure composed of a Mo atom layer and a W atom layer; and correspondingly, the TMDCs heterojunction structure formed in step (3) is preferably a MoS₂/WS₂ heterojunction structure composed of a MoS₂ layer and a WS₂ layer.

Further, in step (1), the bottom electrode layer is specifically provided on the substrate by a thin film deposition process; preferably, in step (1), an ITO film layer is deposited as the bottom electrode layer on the substrate by magnetron sputtering under an oxygen atmosphere; and preferably, the ITO film layer has a thickness of 10 nm to 1,000 nm, and more preferably of 200 nm.

Further, in step (4), the depositing electrode materials for forming the top electrode layer is preferably conducted by depositing electrode metal materials with direct current (DC) sputtering or electron beam evaporation to form the top electrode layer.

Through the above technical solutions conceived in the present invention, the present invention constructs a new memristor totally based on 2D materials, compared with the prior art, which is completely different from conventional MIM structures, and has the following advantages: the present invention prepares a memristor using 2D materials, and thus can make breakthroughs in the aspects of size, flexibility and transparency of the device by taking advantage of many advantages of 2D materials themselves; and the present invention prepares the intermediate dielectric layer of the memristor using a 2D material heterojunction, achieves the memristive function by enabling the transition between high-resistance state (HRS) and low-resistance state (LRS) using the rectification characteristics of the 2D material heterojunction, and improve the performance of the device through the voltage-controlled modulation effect of the heterojunction barrier. The functional layer of heterojunction is a two-layer laminate structure composed of two TMDCs (with one TMDCs corresponding to one layer in the structure). Furthermore, the present invention can adopt the solid-phase sulfuration method based on rapid thermal treatment to realize the rapid single-step preparation of a 2D material heterojunction with high quality, which can improve the growth efficiency of 2D materials, and greatly reduce the growth time and capital cost of device production. The method is specified as follows: a metal laminate structure is prepared first and then sulfurated to give corresponding TMDCs, which can achieve the effective and large-scale production and reduce the production cost. Each structure of the TMDCs layer can also be prepared by mechanical exfoliation, chemical vapor deposition, hydrothermal synthesis or other methods.

The memristor of the present invention has lower operating voltage, reduced fluctuation, significantly-reduced power consumption, and extremely-low thickness, which exhibits prominent advantages for high-density integration. The introduction of a 2D material heterojunction structure enables a high degree of similarity to the information transmission mode of neurons, which will significantly promote the simulation design of the human brain-like computer system in the future.

The present invention adopts a 2D material heterojunction film, which is disposed as an intermediate dielectric layer between a top electrode layer and a bottom electrode layer (the bottom electrode layer, the intermediate dielectric layer and the top electrode layer are disposed on a substrate in sequence; and the substrate can withstand the high temperature of sulfuration treatment, is chemically inactive, and does not react with sulfur vapor) to give a memristor with a heterojunction structure. The 2D material heterojunction film is formed by directly sulfurating a metal layer in high purity sulfur vapor (for example, the present invention can use magnetron sputtering or electron beam evaporation to deposit an elemental metal layer on the bottom electrode, and then use rapid direct sulfuration to form a TMDCs heterojunction structure). The TMDCs heterojunction obtained from sulfuration is a 2D material heterojunction structure composed of two sulfide layers, with a total thickness preferably of 1 nm to 50 nm, which can remarkably reduce the size of the device, so that the free ion movement path of the memristor is reduced during the switching process, thereby improving the efficiency of transition. Moreover, transition metal sulfides such as molybdenum sulfide also have photoelectric response characteristics or the like, which enables the obtained memristors to be used in other special fields such as optoelectronics.

The present invention adopts the heterojunction film obtained by sulfurating the metal atom layer as a functional layer, in combination with the electrode layers, making the memristor exhibit many excellent properties, for example, the thickness of the functional layer of the device is reduced to about 10 nm, and the space required for the three-dimensional (3D) stacking process in the future is significantly reduced. The overall structure of the device is a metal/heterojunction/metal structure (MHM), which is completely different from the traditional MIM structure, and has lower operating voltage, excellent retention and switching stability. The memristor exhibits a high degree of similarity when mimicking the information transmission by neurons. The 2D material heterojunction structure itself is also flexible, and has lower operating voltage and ultra-high integration density, which has a promising prospect in the development of brain-like computing devices in the future.

The present invention adopts 2D materials as the functional layer, and this is mainly because the thickness can be reduced to the atom layer, and the 2D materials have various special properties, such as transparency, flexibility, and light sensitivity. The traditional oxide materials have relatively-monotonous functions and structures, but 2D materials can form a heterojunction through van der Waals forces, which changes the working principle of a memristor, and improves the working stability of the nanoscale device. The present invention preferably adopts a heterojunction as the functional layer of a memristor. The heterojunction can be implemented by using TMDCs, which is more suitable for constructing a memristor. Taking transition metal disulfides as an example, as these transition metal disulfides are most n-type semiconductors, the corresponding heterojunctions have resistance-switching characteristics. Therefore, the memristor with a 2D material heterojunction can properly exhibit LRS or HRS in the presence of a heterojunction interface.

In addition, the present invention also conducts optimization control on the setting of detailed conditions for the preparation method of the memristor; the thickness of the 2D material heterojunction layer obtained from sulfuration is controlled at 1 nm to 50 nm, and preferably at 10 nm; and the temperature for the direct sulfuration is controlled at 500° C. to 1,000° C., and preferably at 550° C. It is found through experiments that the device with an intermediate dielectric layer having a thickness of 10 nm has better stability and relatively-low operating voltage. The sulfuration temperature of 550° C. is relatively low and can meet the requirements for metal sulfuration. In choosing the bottom electrode, it should be noted that the bottom electrode cannot be sulfurated by sulfur vapor and also cannot be easily decomposed at high temperatures. The present invention preferably chooses ITO as the bottom electrode, and more preferably reduces the sulfuration time to 10 min. The present invention preferably further controls the thickness of the entire functional layer of the 2D material heterojunction at 10 nm. As the materials grown by sulfuration have a relatively-high doping concentration, a too-thin heterojunction layer may cause unstable performance of the device. For example, in the case where the overall thickness of the functional layer is small, with molybdenum disulfide and tungsten disulfide having thicknesses of 3 atom layers and 5 atom layers, respectively, the memristor has an extremely-low stability, and will remain at LRS only after 3 to 5 switching cycles between HRS and LRS, which is disadvantageous for applications. When the thickness of the entire functional layer is increased to 10 nm, it is found that the device has improved comprehensive performance, which is due to the fact that the doping concentration of free ions during the growth of materials can better realize the function of the memristor within the vertical movement range of 10 nm. If sulfides are formed by another preparation method, and the doping concentration for materials is artificially controlled; theoretically, the performance of the device can also be better controlled, and the performance can be improved with the functional layer being as thin as possible.

In summary, the memristor of the present invention exhibits many excellent properties, including lower operating voltage, high switching stability, excellent retention or the like; the working principle of the 2D material heterojunction is very close to the process of information transmission by neurons, which is of great significance to the development of artificial intelligence and brain-like neurochips in the future; and moreover, the manufacturing process for the memristor according to the present invention has low complexity and high reliability, and is suitable for large-scale industrial production.

### BRIEF DESCRIPTION OF DRAWINGS

FIG. 1 is a structural diagram for the memristor unit prepared in the present invention.

FIG. 2 is a schematic diagram for specific steps of the preparation method in an example of the present invention.

FIG. 3 is a current-voltage (I-V) characteristic curve for the memristor unit prepared in Example 1 of the present invention.

FIG. 4 shows the switching performance (>100 times) of the memristor unit prepared in Example 1 of the present invention.

FIGS. 5A and 5B show the switching stability of the memristor unit prepared in Example 1 of the present invention, where FIG. 5A shows the stability of HRS and LRS during the switching, and FIG. 5B shows the stability of voltage during the set process and reset process of the switching.

FIGS. 6A and 6B are comparisons of the working process of the memristor unit prepared in Example 1 of the present invention with the process of information transmission by synapses, where, FIG. 6A is a schematic diagram for the working process of the memristor unit prepared in Example 1 of the present invention, and FIG. 6B is a schematic diagram for the process of information transmission by synapses.

FIG. 7 is an I-V characteristic curve for the memristor unit prepared in Example 2 of the present invention.

FIGS. 8A and 8B are I-V characteristic curves for the memristor unit prepared in Example 3 of the present invention, where, FIG. 8A shows the switching performance (>100 times), and FIG. 8B shows the reset process and the set process for the memristor.

FIG. 9 is an I-V characteristic curve for the memristor unit prepared in Example 4 of the present invention.

Among the numerical symbols 1 to 6 in the I-V characteristic curve, 1 to 3 represent the set process, and 4 to 6 represent the reset process.

### DETAILED DESCRIPTION

To make the objectives, technical solutions and advantages of the present invention clearer, the present invention is described in further detail below with reference to the accompanying drawings and examples. It should be understood that the specific examples described herein are merely intended to explain the present invention, rather than to limit the present invention. Further, the technical features involved in the various examples of the present invention described below may be combined with each other to the extent that they do not constitute a conflict with each other.

### EXAMPLE 1

The following example adopts different electrode materials and different intermediate dielectric layers (i.e., different 2D material heterojunction layers) to realize the preparation of novel memristors.

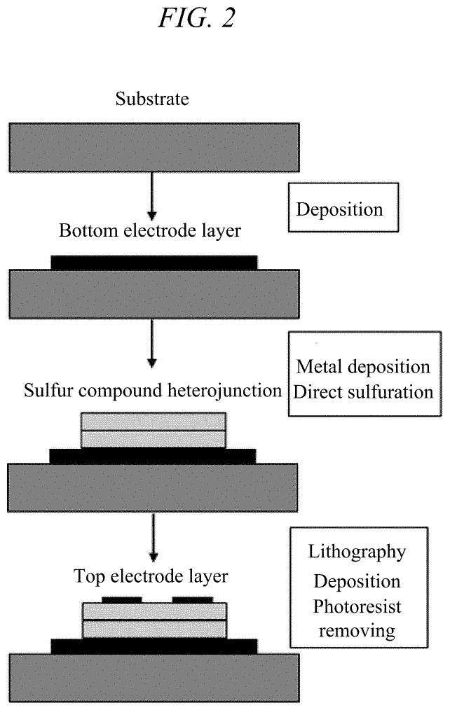

Example 1 is described as follows in conjunction with FIG. 2:

The memristor with a 2D material heterojunction in Example 1 included a bottom electrode layer and a memristive dielectric layer formed on a substrate in sequence, and a top electrode layer formed on the memristive dielectric layer. The memristive dielectric layer was a 2D material heterojunction. In Example 1, the bottom electrode layer was ITO conductive glass; the intermediate memristive dielectric layer was a WS2/MoS2 heterojunction prepared by solid-phase sulfuration, with a thickness of 5 nm; and the top electrode layer was an aluminum film, with a thickness of 100 nm.

The memristor with a 2D material heterojunction of this example was prepared as follows:

1) ITO conductive glasses, as a substrate and bottom electrode for the device, were ultrasonically cleaned with acetone, ethanol and deionized water in sequence, and then blow-dried;

2) an elemental tungsten film was deposited on the bottom electrode film by magnetron sputtering, where the sputtering was conducted with the following parameters: sputtering target: tungsten, sputtering atmosphere: argon, sputtering pressure: 0.6 Pa, substrate temperature: room temperature, sputtering power: 100 W, and sputtering time: 1 min;

3) an elemental molybdenum film was deposited on the elemental tungsten film by magnetron sputtering, where the sputtering was conducted with the following parameters: sputtering target: molybdenum, sputtering atmosphere: argon, sputtering pressure: 0.5 Pa, substrate temperature: room temperature, sputtering power: 100 W, and sputtering time: 1 min;

4) the tungsten and molybdenum films grown by magnetron sputtering in step 2) and step 3) were simultaneously sulfurated and annealed by rapid thermal annealing (RTA), where, the specific parameters could be as follows: heating rate for RTA: 1 to 20° C./s, annealing atmosphere: argon and sulfur vapor, annealing temperature: 500° C. to 600° C. (preferably 550° C.), holding time: 1 min to 30 min, and cooling method: natural cooling to room temperature by water-cooling; and a WS2/MoS2 heterojunction film with a thickness of 5 nm was prepared;

5) a top electrode pattern was formed on the WS2/MoS2 heterojunction film obtained from the annealing in step 4) by UV photolithography, where, a photoresist, which could be AZ5214 photoresist, was applied, then exposed and blow-dried; a top electrode layer of aluminum was deposited by magnetron sputtering, with a thickness of 100 nm; and finally the excessive photoresist was cleaned away to obtain the top electrode layer pattern.

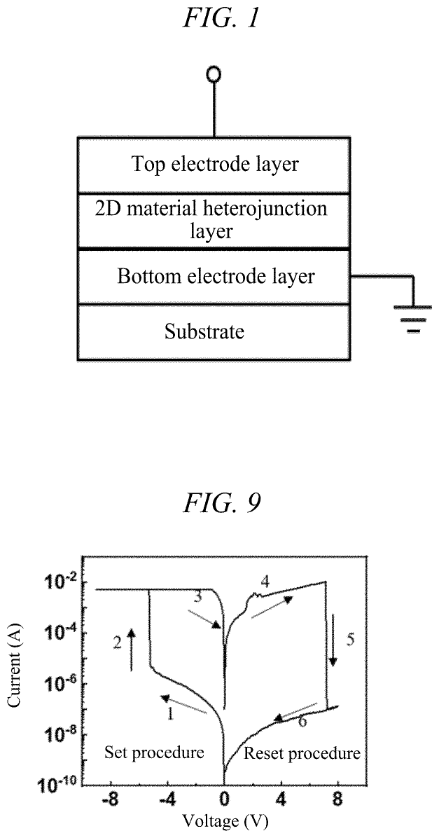

FIG. 1 shows the structural diagram for the memristor prepared in this example, and as shown, the memristor includes a substrate, a bottom electrode layer, a memristive dielectric layer and a top electrode layer in sequence from bottom to top. The substrate and the bottom electrode layer directly adopt ITO conductive glass; the memristive dielectric layer is a 2D material (WS2/MoS2) heterojunction film, with a thickness of 5 nm; and the top electrode is an aluminum film, with a thickness of 100 nm.

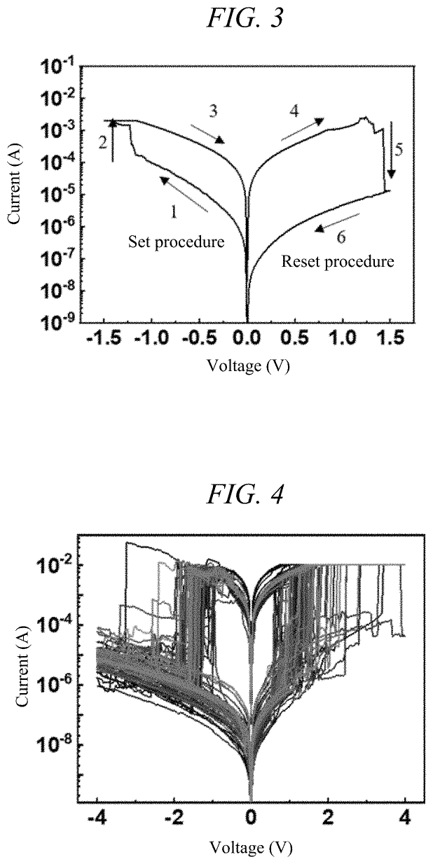

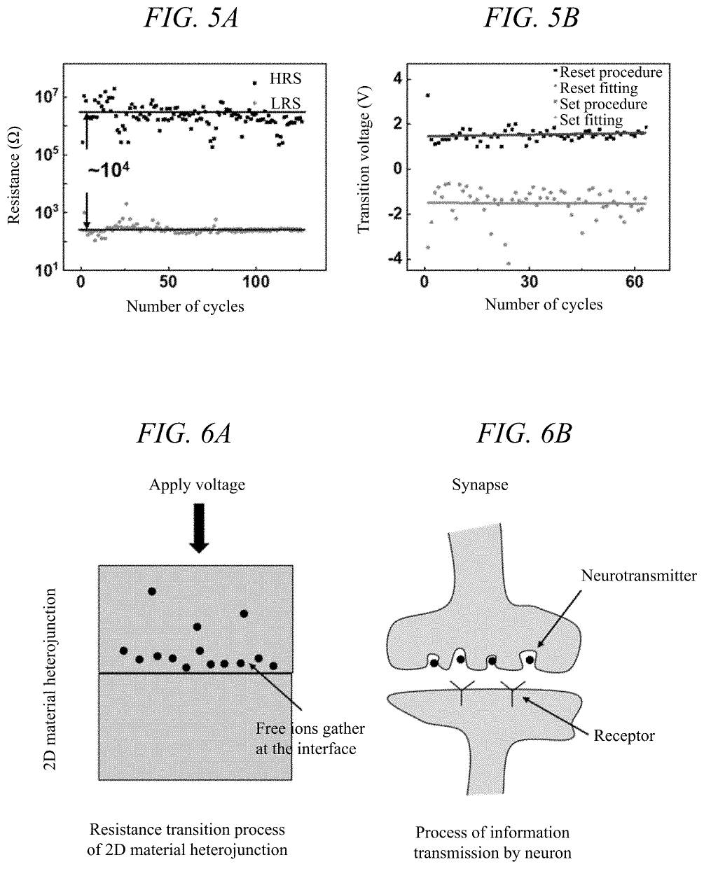

Further, in this example, a semiconductor parameter analyzer B1500A was used to conduct the electrical testing for the memristor with a WS2/MoS2 heterojunction prepared by the above steps. The I-V characteristic curves are shown in FIG. 3, FIG. 4 and FIGS. 5A and 5B.

FIG. 3 shows the I-V characteristic curve for the memristor of this example at initial state under the action of a DC sweeping voltage, and the device exhibits a typical bipolar resistive switching feature. During the testing, the ITO bottom electrode was grounded, and a voltage was applied to the Al top electrode. As the forward voltage applied to the Al electrode increased, at about 1.3 V, the current suddenly increased and the device rapidly changed from HRS to LRS, which was a set process; and as the reverse voltage was further applied, the device returned from LRS to HRS at about −1.1 V, achieving the transition between HRS and LRS, which reveals the resistive switching feature of the memristor with a WS2/MoS2 heterojunction.

FIG. 4 shows the I-V switching performance for the memristor in this example, where the device has 100 cycles.

FIGS. 5A and 5B show the stability characteristics of HRS and LRS and the transition voltage during the cycle of the memristor in this example. It can be concluded from the figure that the on-off ratio (HRS/LRS) of the memristor in this example is greater than 104, and the transition voltage basically remains unchanged during the reset and the set processes of the device.

Due to the presence of a TMDCs heterojunction, the memristor in this example has a different resistive mechanism from a conventional MIM-type memristor. FIGS. 6A and 6B show the comparison of the switching mechanism of the memristor with a 2D material heterojunction of the present invention with the process of information transmission by synapses. As the entire intermediate dielectric layer is a heterojunction composed of two TMDCs, the free ions in the layer cannot move across the grain boundary from one material into another material, but the electron movement is suddenly changed due to the change in the ion concentration. This is similar to the information transmission by neurons, and will definitely play an extremely-important role in the research of brain-like computers in the future.

### EXAMPLE 2

In this example, the specific implementation was the same as that for Example 1, except that the intermediate dielectric layer of WS2/MoS2 heterojunction had a thickness of 20 nm, in which tungsten sulfide and molybdenum sulfide both had a thickness of 10 nm.

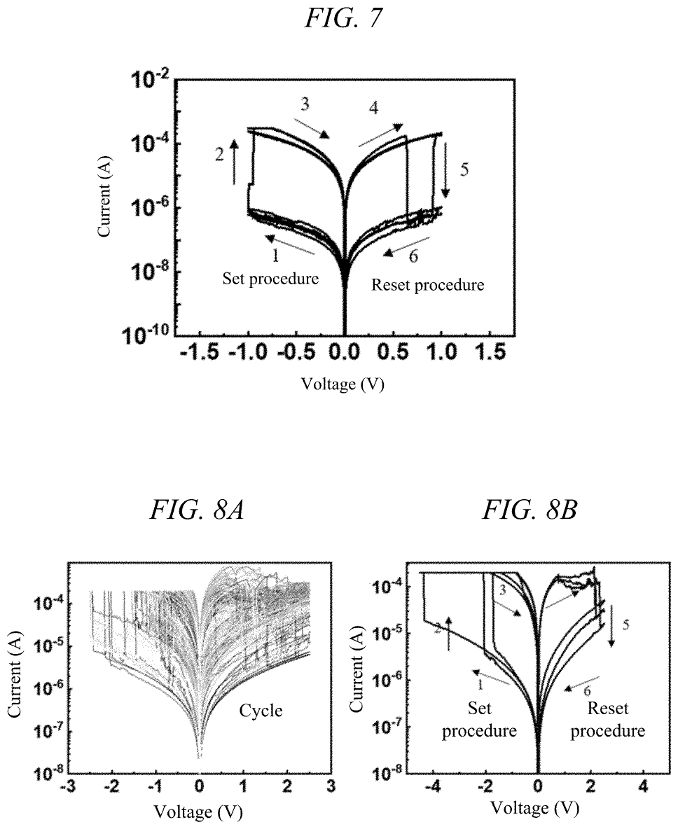

Further, in this example, a semiconductor parameter analyzer was used to conduct the electrical testing for the memristor with a WS2/MoS2 heterojunction. FIG. 7 shows the I-V characteristic curve for the memristor of this example at initial state in responsive to a DC sweeping voltage.

### EXAMPLE 3

In this example, the specific implementation was the same as that for Example 1, except that the top electrode layer was Ag with a thickness of 100 nm.

Further, in this example, a semiconductor parameter analyzer was used to conduct the electrical testing for the memristor with a WS2/MoS2 heterojunction. FIGS. 8A and 8B show I-V characteristic curves for the memristor of this example at initial state in responsive to a DC sweeping voltage.

### EXAMPLE 4

In this example, the specific implementation was the same as that for Example 1, except that the top electrode layer was Au/Ni with a thickness of 80 nm/20 nm, and the bottom electrode layer was graphene.

Further, in this example, a semiconductor parameter analyzer was used to conduct the electrical testing for the memristor with a WS2/MoS2 heterojunction. FIG. 9 shows the I-V characteristic curve for the memristor of this example at initial state in responsive to a DC sweeping voltage.

In addition to what is described in the above examples, the bottom electrode layer and the intermediate dielectric layer can be formed on the substrate using a thin film deposition process. The thin film deposition process includes thermal evaporation, magnetron sputtering, electron beam evaporation, sol-gel, chemical vapor deposition or coating. The thin film deposition process can be flexibly adjusted according to the materials used for the bottom electrode layer and the intermediate dielectric layer. In addition, the substrate may be an insulating substrate, a semiconductor substrate or a conductive substrate. The insulating substrate may include, for example, thermal oxide silicon wafer, glass, ceramic or plastic; the semiconductor substrate may include, for example, silicon, oxide semiconductor, nitride semiconductor or other semiconductor materials; and the conductive substrate may include, for example, metal or graphene. The present invention preferably adopts the SiO2/Si material with an oxide layer formed from oxidation of the monocrystalline silicon surface (i.e., thermal oxide silicon wafer) as a substrate, which mainly considers the compatibility with existing CMOS processes and the applications in the field of integrated electronics. The substrate may also be another silicon-based substrate.

It is easy for those skilled in the art to understand that the above-mentioned contents are merely the preferred examples of the present invention, and are not intended to limit the present invention. Any modifications, equivalent substitutions and improvements made within the spirit and principles of the present invention should fall within the protection scope of the present invention.

What is claimed is:

1. A memristor with a two-dimensional (2D) material heterojunction, comprising:
a substrate;
a bottom electrode layer;
a 2D material heterojunction layer; and
a top electrode layer from bottom to top;
wherein the 2D material heterojunction layer serves as an intermediate dielectric layer with a thickness of 1 nm to 50 nm, and has a two-layer laminate structure composed of two different transitional metal dichalcogenides (TMDCs), with one layer in the laminate structure corresponding to one of the TMDCs.

2. The memristor with a 2D material heterojunction according to claim 1, wherein:
the 2D material heterojunction layer is formed by directly sulfurating a metal laminate structure in high purity sulfur vapor;
the metal laminate structure comprises two layers of elemental metal structures; and
the two layers comprise metal elements different from each other.

3. The memristor with a 2D material heterojunction according to claim 2, wherein:
the direct sulfuration is conducted at 500° C. to 1,000° C. for 1 min to 30 min; and
the 2D material heterojunction layer has a thickness of about 10 nm, and the direct sulfuration is conducted at about 550° C. for 10 min.

4. The memristor with a 2D material heterojunction according to claim 1, wherein:
the two different TMDCs are specifically two different transition metal disulfides; and
the transition metal sulfides are any two of zinc sulfide, silver sulfide, titanium sulfide, cadmium sulfide, cuprous sulfide, germanium sulfide, tungsten sulfide and molybdenum sulfide.

5. The memristor with a 2D material heterojunction according to claim 2, wherein:
the substrate is a rigid substrate or a flexible substrate and can withstand a high temperature of at least 500° C., and will not react with the sulfur vapor; and
the rigid substrate is a SiO₂/Si substrate with an oxide layer formed from oxidation of the monocrystalline silicon surface, or a sapphire substrate.

6. The memristor with a 2D material heterojunction according to claim 1, wherein:
the top electrode layer is Au, Ti, Pt, Al, W, Ag, Cu, ITO, TiN or graphene, with a thickness of about 80 nm to 200 nm;
the top electrode layer is Al, with a thickness of about 100 nm;
the material used for the bottom electrode layer is any one of metal, conductive oxide, conductive nitride and conductive carbon material, with a thickness of about 1 nm to 500 nm; and preferably, the material used for the bottom electrode layer is a conductive oxide, preferably ITO with a thickness of 10 nm to 1,000 nm, and more preferably ITO with a thickness of 200 nm.

7. A method for preparing a memristor with a 2D material heterojunction, the method comprising:
(1) preparing a substrate provided with a bottom electrode layer on the surface thereof;
(2) depositing a metal laminate structure on the bottom electrode layer by a thin film deposition process with a shadow mask, wherein, the thin film deposition process is thermal evaporation, magnetron sputtering, electron beam evaporation, sol-gel, chemical vapor deposition or coating;
(3) treating, using a direct vacuum sulfuration method, the substrate deposited with the metal laminate structure, so that the metal laminate structure is sulfurated to form a TMDCs heterojunction structure; and
(4) spin-coating a photoresist on the heterojunction structure, and defining a top electrode pattern on the photoresist by lithography; then depositing electrode materials for forming a top electrode layer, and then stripping the photoresist to form the top electrode layer, thereby achieving the memristor with a 2D material heterojunction.

8. The method according to claim 7, wherein:
the 2D material heterojunction layer is formed by directly sulfurating a metal laminate structure in high purity sulfur vapor;
the metal laminate structure comprises two layers of elemental metal structures; and
the two layers comprise metal elements different from each other.

9. The method according to claim 8, wherein:
the direct sulfuration is conducted at about 500° C. to 1,000° C. for 1 min to 30 min; and
the 2D material heterojunction layer has a thickness of about 10 nm, and the direct sulfuration is conducted at about 550° C. for 10 min.

10. The method according to claim 7, wherein:
the two different TMDCs are specifically two different transition metal disulfides; and
the transition metal sulfides are any two of zinc sulfide, silver sulfide, titanium sulfide, cadmium sulfide, cuprous sulfide, germanium sulfide, tungsten sulfide and molybdenum sulfide.

11. The method according to claim 8, wherein:
the substrate is a rigid substrate or a flexible substrate and can withstand a high temperature of at least 500° C., and will not react with the sulfur vapor; and
the rigid substrate is a SiO₂/Si substrate with an oxide layer formed from oxidation of the monocrystalline silicon surface, or a sapphire substrate.

12. The method according to claim 7, wherein:
the top electrode layer is Au, Ti, Pt, Al, W, Ag, Cu, ITO, TiN or graphene, with a thickness of about 80 nm to 200 nm;
the top electrode layer is Al, with a thickness of about 100 nm;
the material used for the bottom electrode layer is any one of metal, conductive oxide, conductive nitride and conductive carbon material, with a thickness of about 1 nm to 500 nm;
and preferably, the material used for the bottom electrode layer is a conductive oxide, preferably ITO with a thickness of 10 nm to 1,000 nm, and more preferably ITO with a thickness of 200 nm.

13. The method according to claim 7, wherein:
in step (2), the metal laminate structure is specifically deposited on the bottom electrode layer by magnetron sputtering or electron beam evaporation;
in step (2), the metal laminate structure is a two-layer metal structure composed of a Mo atom layer and a W atom layer; and
correspondingly, the TMDCs heterojunction structure formed in step (3) is specifically a MoS₂/WS₂ heterojunction structure composed of a MoS₂ layer and a WS₂ layer.

14. The method according to claim 8, wherein:
in step (2), the metal laminate structure is specifically deposited on the bottom electrode layer by magnetron sputtering or electron beam evaporation;
in step (2), the metal laminate structure is a two-layer metal structure composed of a Mo atom layer and a W atom layer; and
correspondingly, the TMDCs heterojunction structure formed in step (3) is specifically a MoS₂/WS₂ heterojunction structure composed of a MoS₂ layer and a WS₂ layer.

15. The method according to claim 9, wherein:
in step (2), the metal laminate structure is specifically deposited on the bottom electrode layer by magnetron sputtering or electron beam evaporation;
in step (2), the metal laminate structure is a two-layer metal structure composed of a Mo atom layer and a W atom layer; and
correspondingly, the TMDCs heterojunction structure formed in step (3) is specifically a MoS₂/WS₂ heterojunction structure composed of a MoS₂ layer and a WS₂ layer.

16. The method according to claim 10, wherein:
in step (2), the metal laminate structure is specifically deposited on the bottom electrode layer by magnetron sputtering or electron beam evaporation;
in step (2), the metal laminate structure is a two-layer metal structure composed of a Mo atom layer and a W atom layer; and
correspondingly, the TMDCs heterojunction structure formed in step (3) is specifically a MoS₂/WS₂ heterojunction structure composed of a MoS₂ layer and a WS₂ layer.

17. The method according to claim 11, wherein:
in step (2), the metal laminate structure is specifically deposited on the bottom electrode layer by magnetron sputtering or electron beam evaporation;
in step (2), the metal laminate structure is a two-layer metal structure composed of a Mo atom layer and a W atom layer; and
correspondingly, the TMDCs heterojunction structure formed in step (3) is specifically a MoS₂/WS₂ heterojunction structure composed of a MoS₂ layer and a WS₂ layer.

18. The method according to claim 12, wherein:
in step (2), the metal laminate structure is specifically deposited on the bottom electrode layer by magnetron sputtering or electron beam evaporation;
in step (2), the metal laminate structure is a two-layer metal structure composed of a Mo atom layer and a W atom layer; and
correspondingly, the TMDCs heterojunction structure formed in step (3) is specifically a MoS₂/WS₂ heterojunction structure composed of a MoS₂ layer and a WS₂ layer.

19. The method according to claim 7, wherein:
in step (1), the bottom electrode layer is specifically provided on the substrate by a thin film deposition process;
preferably, in step (1), specifically, an ITO film layer is deposited as the bottom electrode layer on the substrate by magnetron sputtering under an oxygen atmosphere; and more preferably, the ITO film layer has a thickness of 10 nm to 1,000 nm, and more preferably of 200 nm.

20. The method according to claim 7, wherein:
in step (4), the depositing electrode materials for forming the top electrode layer is specifically conducted by depositing electrode metal materials with magnetron sputtering or electron beam evaporation to form the top electrode layer.
